(19) United States
(12) Patent Application Publication
(10) Pub. No.: US 2026/0223457 A1
(43) Pub. Date: Jul. 30, 2026

(54) DISPLAY PANEL AND DISPLAY DEVICE

(71) Applicant: Guangzhou China Star Optoelectronics Semiconductor Display Technology Co., LTd., Guangzhou (CN)

(72) Inventors: Yuanjun HSU, Guangzhou (CN); Xiaolin YAN, Guangzhou (CN); Weiran CAO, Guangzhou (CN); Bin ZHAO, Guangzhou (CN); Yunxi LIU, Guangzhou (CN); Xiaoxing ZHANG, Guangzhou (CN)

(73) Assignee: Guangzhou China Star Optoelectronics Semiconductor Display Technology Co., LTd., Guangzhou (CN)

(21) Appl. No.: 19/248,316

(22) Filed: Jun. 24, 2025

(30) Foreign Application Priority Data
Jan. 24, 2025 (CN) 202510122890.1

(51) Int. Cl. H10D 86/40; H10D 30/67; H10D 86/01; H10D 86/60

(52) U.S. Cl. CPC H10D 86/431; H10D 30/6731; H10D 30/6757; H10D 86/0221; H10D 86/441; H10D 86/60

(57) ABSTRACT

A display panel and a display device are provided. The display panel includes a first thin film transistor located in a display area. The first thin film transistor includes a first gate and a second gate, and the first gate is located on a side of the second gate away from the first electrode. The first gate includes a semiconductor portion and a conductor portion connected to each other, and the conductor portion is located on a side of the semiconductor part close to the second electrode. In a thickness direction, the second gate overlaps the first channel, and the semiconductor portion partially overlaps the first channel and the second gate.

### CROSS-REFERENCE TO RELATED APPLICATIONS

This application claims priority to and the benefit of Chinese Patent Application No. 202510122890.1 filed on Jan. 24, 2025, the disclosure of which is incorporated herein by reference in its entirety.

### TECHNICAL FIELD

The present disclosure relates to the technical field of displays, and more particularly to a display panel and a display device.

### BACKGROUND

In the organic light-emitting diode display panel, a conventional indium gallium zinc oxide (IGZO) thin film transistor is used in the display area to achieve high stability of driving current output, and a high mobility oxide thin film transistor is used in the gate driving circuit area to achieve smaller device size and high driving capability. Compared with the gate driving circuit area, the display area has more layers of gate insulating layers, and the more layers of gate insulating layers, the greater the difference in uniformity of its stacked structure, thus affecting the uniformity and stability of thin film transistors. However, the high mobility oxide thin film transistor in the gate driving circuit area is a single-layer gate insulating layer. In the dry etching process of the gate insulating layer, the amount of overetching is large, which makes it difficult to control the length of the channel. In addition, the driving thin film transistor of the display area is single-gate control, which cannot control the output characteristics of the driving thin film transistor.

### SUMMARY

An embodiment of the present disclosure provides a display panel, which includes a display area and a gate driving circuit area located at least on one side of the display area, where the display panel includes:
a substrate;
a first thin film transistor disposed in the display area, where the first thin film transistor includes a first gate, a first insulating layer, a first active layer, a second insulating layer, a second gate, a first electrode, and a second electrode, the first active layer includes a first contacting portion, a first channel, and a second contacting portion, the first gate is disposed on the substrate, the first insulating layer covers the first gate, the first active layer is disposed on a side of the first insulating layer away from the substrate, the second insulating layer is disposed on a side of the first active layer away from the substrate, the second gate is disposed on a side of the second insulating layer away from the substrate, the first electrode is connected to the first contacting portion, and the second electrode is connected to the second contacting portion;
where the first gate is located on a side of the second gate away from the first electrode, the first gate includes a semiconductor portion and a conductor portion connected to each other, the conductor portion is located on a side of the semiconductor portion close to the second electrode, the second gate overlaps the first channel in a thickness direction of the display panel, and the semiconductor portion partially overlaps the first channel and the second gate in the thickness direction of the display panel.

Accordingly, an embodiment of the present disclosure further provides a display device including the display panel described in any one of the above embodiments.

### BRIEF DESCRIPTION OF THE DRAWINGS

FIG. 1 is a schematic structural view of a display panel provided by an embodiment of the present disclosure.

FIG. 2 is a partial structural schematic view of the display panel provided by an embodiment of the present disclosure.

FIG. 3 is a schematic view in step B01 of a manufacturing method of the display panel provided by an embodiment of the present disclosure.

FIG. 4 is a schematic view in step B02 of a manufacturing method of the display panel provided by an embodiment of the present disclosure.

FIG. 5 is a schematic view in step B03 of a manufacturing method of the display panel provided by an embodiment of the present disclosure.

FIG. 6 is a schematic view in step B04 of a manufacturing method of the display panel provided by an embodiment of the present disclosure.

FIG. 7 is a schematic view in step B05 of a manufacturing method of the display panel provided by an embodiment of the present disclosure.

FIG. 8 is a schematic view in step B06 of a manufacturing method of the display panel provided by an embodiment of the present disclosure.

FIG. 9 is a schematic view in step B07 of a manufacturing method of the display panel provided by an embodiment of the present disclosure.

FIG. 10 is a schematic structural view of a display device provided by an embodiment of the present disclosure.

### DETAILED DESCRIPTION

The technical solution in the embodiment of the present disclosure will be clearly and completely described below with reference to the accompanying drawings in the embodiments of the present disclosure. Apparently, the described embodiments are merely some embodiments of the present application instead of all embodiments. Based on the embodiments in the present disclosure, all other embodiments obtained by a person skilled in the art without any inventive effort are within the scope of the present disclosure. In addition, it should be understood that the specific embodiments described here are only used to illustrate and explain the present disclosure, and are not used to limit the present disclosure. In the present application, various embodiments may be combined with each other without further elaboration, and in the absence of any indication to the contrary, the terms “upper” and “lower” are generally used to refer to the upper and lower direction of the device in the actual use or working state, specifically the direction of the drawing in the accompanying drawings. The terms “inside” and “outside” refer to the outline of the device. The terms “first”, “second”, “third”, etc., are used only as indications and do not impose numerical requirements or establish an order.

The embodiments of the present disclosure provide a display panel and a display device, which will be described in detail below. It should be noted that the order of description of the following embodiments is not intended to limit the preferred order of embodiments.

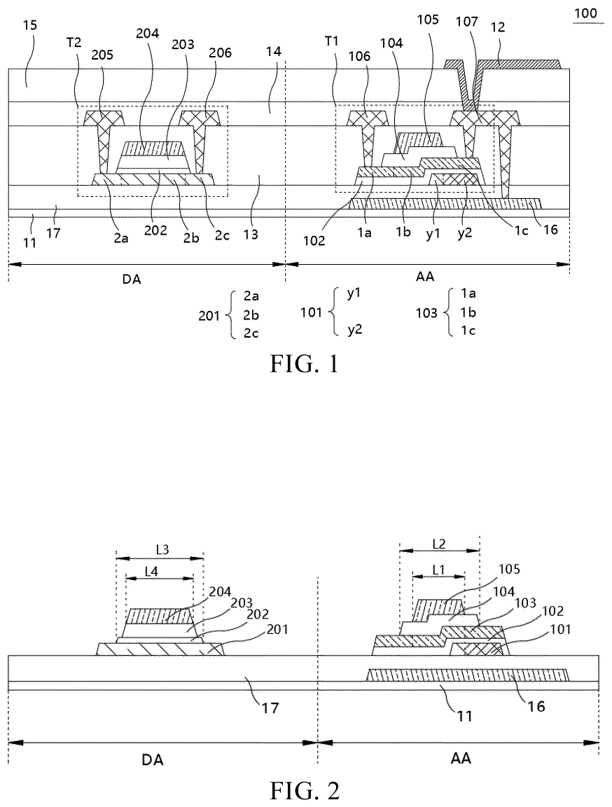

Referring to FIGS. 1 and 2, an embodiment of the present disclosure provides a display panel 100 including a display area AA and a gate driving circuit area DA located at least on one side of the display area AA. The display panel 100 includes a substrate 11, a first thin film transistor T1, and a second thin film transistor T2. The first thin film transistor T1 is provided in the display area AA, and the second thin film transistor T2 is provided in the gate driving circuit area DA.

The first thin film transistor T1 includes a first gate 101, a first insulating layer 102, a first active layer 103, a second insulating layer 104, a second gate 105, a first electrode 106, and a second electrode 107. The first active layer 103 includes a first contacting portion 1a, a first channel 1b, and a second contacting portion 1c. The first gate 101 is provided on the substrate 11. The first insulating layer 102 covers the first gate 101. The first active layer 103 is provided on a side of the first insulating layer 102 away from the substrate 11. The second insulating layer 104 is provided on a side of the first active layer 103 away from the substrate 11. The second gate 105 is provided on a side of the second insulating layer 104 away from the substrate 11. The first electrode 106 is connected to the first contacting portion 1a, and the second electrode 107 is connected to the second contacting portion 1c.

The first gate 101 is located on a side of the second gate 105 away from the first electrode 106. The first gate 101 includes a semiconductor portion y1 and a conductor portion y2 connected to each other, and the conductor portion y2 is located on a side of the semiconductor portion y1 close to the second electrode 107. In a thickness direction of the display panel 100, the second gate 105 overlaps the first channel 1b, and the semiconductor portion y1 partially overlaps the first channel 1b and the second gate 105.

Optionally, the display panel 100 is an electroluminescent panel, and the second electrode 107 is connected to the anode 12. Hereinafter, the display panel 100 being an electroluminescent panel is taken as an example.

It can be understood that the first gate 101 is provided on the side close to the second electrode 107 to control the output saturation characteristic of the output electrode area of the first thin film transistor T1 so as to improve the output characteristic of the pixel driving transistor. The semiconductor portion y1 is provided to overlap the first channel 1b, and the conductor portion y2 is provided on the side close to the output electrode of the first thin film transistor T1, so that the potential of the semiconductor portion y1 is relative low compared to the potential of the conductor portion y2 based on the larger impedance of the semiconductor portion y1 and the smaller impedance of the conductor portion y2. This configuration reduces the influence of the electric field from the first gate electrode 101 on the first channel 1b, thereby enhancing the service life of the first thin film transistor T1. Additionally, the first gate electrode 101 can generate two different potentials to collaboratively regulate the electric field distribution in the output region of the first thin film transistor T1, achieving control over its output saturation characteristics and improving its stability.

It should be noted that the second electrode 107 serves as the output electrode of the first thin film transistor T1, and is connected to the anode 12.

Optionally, the display panel 100 further includes an interlayer dielectric layer 13, a passivation layer 14, a planarization layer 15, a light shielding layer 16, and a buffer layer 17. The interlayer dielectric layer 13 covers the second gate 105 and the substrate 11, and the first electrode 106 and the second electrode 107 are provided on a side of the interlayer dielectric layer 13 away from the substrate 11. The passivation layer 14 covers the first electrode 106, the second electrode 107, and the interlayer dielectric layer 13. The planarization layer 15 covers the passivation layer 14. The anode 12 is disposed on a side of the flat layer 15 away from the substrate 11. The light shielding layer 16 is provided on the substrate 11 and overlaps the first thin film transistor T1. The buffer layer 17 covers the light shielding layer 16 and the substrate 11. The first gate 101 is provided on a side of the buffer layer 17 away from the substrate 11.

In some embodiments, the interlayer dielectric layer 13 may also be omitted so that the first electrode 106 and the second electrode 107 are directly lap-jointed with the first active layer 103.

The display panel 100 further includes a light-emitting functional layer and a cathode, and the light-emitting functional layer and the cathode are sequentially stacked on the anode 12.

Optionally, the material of the light-emitting layer of the light-emitting functional layer may be an organic material, such as Alq3, Bis(2-methyl-8-quinolinolato-N1,O8)-(1,1′-Biphenyl-4-olato)aluminum (BAlq), DPVBi, Almq3, 3-tert-butyl-9, or 2-tertbutyl-9,10-di(2-naphthyl)anthracene (TBADN).

The material of the light-emitting layer may be an inorganic material, and may be, for example, selected from one or more of group IV semiconductor nanocrystals, group II-V semiconductor nanocrystals, group II-VI semiconductor nanocrystals, group IV-VI semiconductor nanocrystals, group III-V semiconductor nanocrystals, and group III-VI semiconductor nanocrystals. Examples include one or more of silicon quantum dots, germanium quantum dots, cadmium sulfide quantum dots, cadmium selenide quantum dots, cadmium telluride quantum dots, zinc selenide quantum dots, lead sulfide quantum dots, lead selenide quantum dots, indium phosphide quantum dots, indium arsenide quantum dots, gallium nitride quantum dots, and the like.

Optionally, the material of the first active layer 103 includes at least an amorphous metal oxide material containing indium, gallium, and zinc. Optionally, the material of the first channel 1b is an amorphous metal oxide containing indium, gallium, and zinc.

Optionally, each of the first thin film transistor T1 and the second thin film transistor T2 may be one of a P-type or an N-type. In the embodiments of the present disclosure, the first thin film transistor T1 and the second thin film transistor T2 being N-type are taken as an example.

Optionally, in some embodiments of the present disclosure, a carrier mobility of the semiconductor portion y1 is greater than a carrier mobility of the first channel 1b, so that the conductivity of the semiconductor portion y1 is greater than the conductivity of the first channel 1b.

It should be understood that according to the current formula of the saturation area of the thin film transistor, when Vds gradually increases, the local electric field of the drain (output electrode) is neutralized by the interaction of Vds and Vgs, leading to the pinch-off of the carrier channel of the channel, and the current no longer increases with the increase of Vds. The first gate 101 is provided close to the output electrode and at a certain potential, so that the local electric field of the output electrode area may be regulated and the saturation current may be increased. As a part of the first gate 101, the semiconductor portion y1 needs a certain conductivity to provide a potential, and then forms an electric field to micro-control the saturation output characteristic of the thin film transistor, so that the conductivity of the semiconductor portion y1 is provided ranging between the conductivity of the first channel 1b and the conductivity of the conductor portion y2, and the first gate 101 has a gradual potential to form a more adaptable local electric field, so as to better control the saturation output characteristic of the first thin film transistor T1.

Optionally, the material of the semiconductor portion y1 may be an amorphous or polycrystalline high-mobility metal oxide material. The material of the conductor portion y2 includes all the materials of the semiconductor portion y1 and conductive ions, and the conductive ions may be N-type or P-type ions.

Optionally, in some embodiments of the present disclosure, in the thickness direction of the display panel 100, the conductor portion y2 and the second contacting portion 1c at least partially overlap, and the conductor portion y2 and the second electrode 107 partially overlap.

It can be understood that the conductor portion y2 corresponds to the second contacting portion 1c, so that the second contacting portion 1c is raised so that the second electrode 107 may be connected to the second contacting portion 1c through a shallow via hole. The distance between the second electrode 107 and the second contacting portion 1c is shortened, and the signal transmission efficiency is improved.

Optionally, in some embodiments of the present disclosure, a portion of the first insulating layer 102 covers the first gate 101 to form a structure having a height difference, and the first active layer 103 covers the first insulating layer 102 along the structure to form a first channel 1b having a height difference.

It can be understood that the first gate 101 raises a part of the first channel 1b so that the first channel 1b has a stepped shape, which increases the length of the first channel 1b, reduces the risk of leakage current, and further improves the stability of the first thin film transistor T1.

Optionally, in some embodiments of the present disclosure, the material of the first channel 1b is a metal oxide semiconductor, the material of the first insulating layer 102 is a first oxysilicon, and the material of the second insulating layer 104 is a second oxysilicon, and the oxygen content of the second oxysilicon is greater than the oxygen content of the first oxysilicon.

It can be understood that a larger oxygen content in the gate insulating layer means a lower concentration of oxygen vacancies therein. The oxygen vacancies are one of the main sources of carriers in the oxide semiconductor, and reducing oxygen vacancies is beneficial to reduce the concentration of carriers to lower the mobility.

In the embodiments of the present disclosure, the first insulating layer 102 and the second insulating layer 104 serve as gate insulating layers, where the oxygen content of the first insulating layer 102 is lower than that of the second insulating layer 104. This design ensures that the carrier mobility in the carrier channel of the second insulating layer 104 is higher, while the carrier mobility in the carrier channel of the first insulating layer 102 is lower, thereby regulating carrier mobility and enhancing the stability of the first thin film transistor T1.

Optionally, in some embodiments of the present disclosure, the thickness of the first insulating layer 102 is less than the thickness of the second insulating layer 104.

It can be understood that with the same gate voltage and gate material, the thinner the gate insulating layer, the larger the gate capacitance, and the lower the required threshold voltage. Therefore, since the conductivity of the first gate 101 is weak, the thickness of the first insulating layer 102 may be reduced to increase the electric field strength, so as to better control the output saturation characteristics of the first thin film transistor T1.

Optionally, referring to FIG. 2, in some embodiments of the present disclosure, the width L2 of the second insulating layer 104 is greater than the width L1 of the second gate 105.

It can be understood that in the process of dry etching of the second insulating layer 104, oxygen vacancies may diffuse in the direction of the first channel 1b, resulting in shortening of the channel. Therefore, the width of the second insulating layer 104 is provided to be greater than the width of the second gate 105, so that oxygen vacancies do not diffuse into the first channel 1b, and the length of the first channel 1b may be accurately controlled, thereby improving the stability of the first thin film transistor T1.

Optionally, the width L1 of the second gate 105 is the length of the first channel 1b.

Optionally, the edge of the second insulating layer 104 is at least 0.5 microns beyond the edge of the second gate 105. Such an arrangement makes it possible to greatly reduce the risk that the oxygen vacancies diffuse into the first channel 1b in the process of dry etching the second insulating layer 104.

Optionally, the edge of the second insulating layer 104 may be 0.5 microns, 0.6 microns, 0.7 microns, 0.8 microns, 0.9 microns, or 1 micron beyond the edge of the second gate 105.

Optionally, in some embodiments of the present disclosure, the display panel 100 further includes a second thin film transistor T2 located in the gate driving circuit area DA. The second thin film transistor T2 includes a second active layer 201, an etching stop layer 202, a third insulating layer 203, a third gate 204, a third electrode 205, and a fourth electrode 206. The second active layer 201 includes a third contacting portion 2a, a second channel 2b, and a fourth contacting portion 2c. The second active layer 201 is provided on the substrate 11. The etching stop layer 202, the third insulating layer 203, and the third gate 204 are sequentially stacked on the second active layer 201. The third gate 204 is provided overlapping the second channel 2b. The third electrode 205 is connected to the third contacting portion 2a, and the fourth electrode 206 is connected to the fourth contacting portion 2c.

The carrier mobility of the second channel 2b is greater than the carrier mobility of the first channel 1b. The second active layer 201 and the first gate 101 are provided in the same layer, and the material of the second channel 2b is the same as that of the semiconductor portion y1.

As can be understood, the carrier mobility of the second channel 2b is greater than the carrier mobility of the first channel 1b, so that the second thin film transistor T2 located in the gate driving circuit area DA has a characteristic of high mobility to meet the requirements of the gate driving circuit.

In the embodiment of the present disclosure, the second active layer 201 and the first gate 101 are formed by the same photomask process, which on the one hand saves the process steps and simplifies the structure of the display panel 100, and on the other hand, optimizing the local electric field formed by the first gate 101 by using a semiconductor material with high mobility as the first gate 101, so as to better control the output saturation characteristics of the first thin film transistor T1.

Optionally, the second active layer 201 is disposed on the side of the buffer layer 17 away from the substrate 11. The material of the second active layer 201 may be an amorphous or polycrystalline high mobility metal oxide material.

Optionally, in some embodiments of the present disclosure, the conductivity of the third contacting portion 2a and the conductivity of the fourth contacting portion 2c are greater than the conductivity of the conductor portion y2.

The conductivity of the third contacting portion 2a and the conductivity of the fourth contacting portion 2c is greater than the conductivity of the first contacting Portion 1a and the second contacting portion 1c.

It can be understood that the conductivity of the conductor portion y2 ranges between the conductivity of the second contacting portion 1c and the conductivity of the semiconductor portion y1, so that the conductivity of the conductor portion y2 is not too large, and the amount of charge of the conductor portion y2 is not too large per unit time, so as to regulate the capacitance of the first gate 101 and further better adjust the output saturation characteristic of the first thin film transistor T1.

The conductivity of the third contacting portion 2a and the conductivity the fourth contacting portion 2c are high, while the conductivity of the first contacting portion 1a and the conductivity of the second contacting portion 1c are low, so as to further satisfy the requirements of the high stability of the first thin film transistor T1 and the high mobility of the second thin film transistor T2.

Optionally, in some embodiments of the present disclosure, the width L3 of the etching stop layer 202 is greater than the width L4 of the third gate 204. The width L3 of the etching stop layer 202 is greater than the width of the third insulating layer 203.

It can be understood that in the process of dry etching the etching stop layer 202, oxygen vacancies diffuse toward the direction of the second channel 2b, resulting in shortening of the channel. Therefore, the width of the etching stop layer 202 is provided to be greater than the width of the third insulating layer 203, so that oxygen vacancies do not diffuse into the second channel 2b, and the length of the second channel 2b may be accurately controlled.

The thickness of the etching stop layer 202 is less than the thickness of the third insulating layer 203, and when the third insulating layer 203 is etched, the etching stop layer 202 may block the etching gas from etching the second active layer 201. When the dry etching of the etching stop layer 202 is subsequently performed, since the thickness of the etching stop layer 202 is thin, the etching time is shorter, and the diffusion time of the oxygen vacancy may be reduced, and the length of the second channel 2b may be more accurately controlled.

Optionally, in some embodiments, the edge of the etching stop layer 202 is at least 0.5 microns beyond the edge of the third gate 204. Such an arrangement makes it possible to greatly reduce the risk that the oxygen vacancies diffuse into the second channel 2b in the process of etching the etching stop layer 202 in the dry etching process.

Optionally, the edge of the etching stop layer 202 may be 0.5 microns, 0.6 microns, 0.7 microns, 0.8 microns, 0.9 microns, or 1 micron beyond the edge of the third gate 204.

Optionally, in some embodiments of the present disclosure, the material of the second channel 2b is a metal oxide semiconductor, the material of the etching stop layer 202 is the first oxysilicon, the material of the third insulating layer 203 is the second oxysilicon, and the oxygen content of the second oxysilicon is greater than the oxygen content of the first oxysilicon.

In the embodiments of the present disclosure, the etching stop layer 202 serves as a gate insulating layer directly contacting the second channel 2b. The low oxygen content in the etching stop layer 202 may increase the mobility of the carrier channels in the etching stop layer 202, thereby improving the mobility of the second thin film transistor T2.

Optionally, in some embodiments, the etching stop layer 202 and the first insulating layer 102 may each be a single film layer, or may be formed by stacking at least two film layers.

Optionally, in some embodiments of the present disclosure, the etching stop layer 202 and the first insulating layer 102 are made of the same material and are made of the same photomask. The third insulating layer 203 and the second insulating layer 104 are made of the same material and are made of the same photomask. The second active layer and the first gate 101 are made of the same photomask. The second gate 105 and the third gate 204 are made of the same material and are made of the same photomask.

It can be understood that some film layers of the first thin film transistor T1 and the second thin film transistor T2 are formed by the same photomask process, so that the number of photomasks may be saved to the greatest extent and the structure may be simplified.

Optionally, the manufacturing method of the display panel 100 provided by the embodiments of the present disclosure includes the following steps B01 to B07.

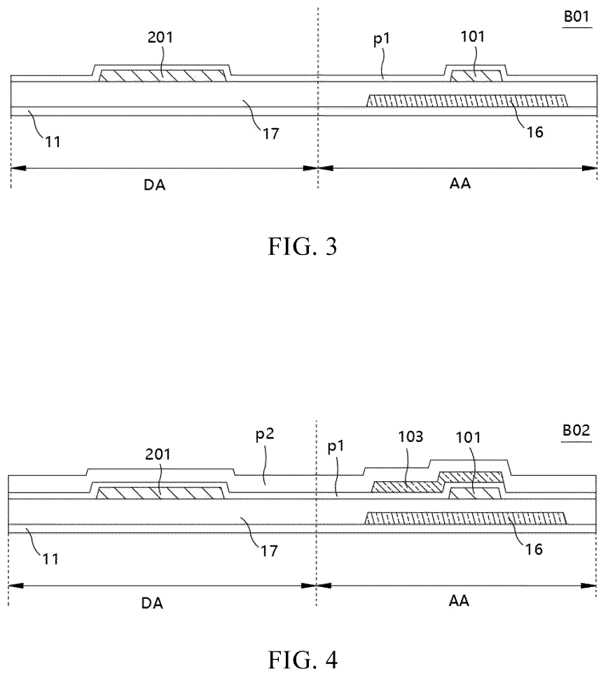

As shown in FIG. 3, in step B01, the light shielding layer 16, the buffer layer 17, the first semiconductor layer, and the first insulating material layer p1 are sequentially formed on the substrate 11.

Optionally, the material of the light shielding layer 16 may be a laminated structure of an alloy of molybdenum and copper. The buffer layer 17 may be a single layer or a stacked layer structure, and the material of the buffer layer 17 is at least one of silicon oxygen, silicon nitride, and silicon oxynitride.

The first semiconductor layer includes a first gate 101 located in the display area AA and a second active layer 201 located in the gate driving circuit area DA. The material of the first semiconductor layer may be an amorphous or polycrystalline high mobility metal oxide material.

The first insulating material layer p1 may consist of a single film layer or may consist of a stack of at least two film layers, and the material of the first insulating material layer p1 may be oxysilicon having a first oxygen content.

As shown in FIG. 4, in step B02, a first active layer 103 and a second insulating material layer p2 are sequentially formed on the first insulating material layer p1, and a part of the first active layer 103 covers the first gate 101. The second insulating material layer p2 covers the first active layer 103 and the first insulating material layer p1.

Optionally, the first active layer 103 is an amorphous metal oxide material containing indium, gallium, and zinc. The material of the second insulating material layer p2 may be oxysilicon having a second oxygen content. The second oxygen content is greater than the first oxygen content.

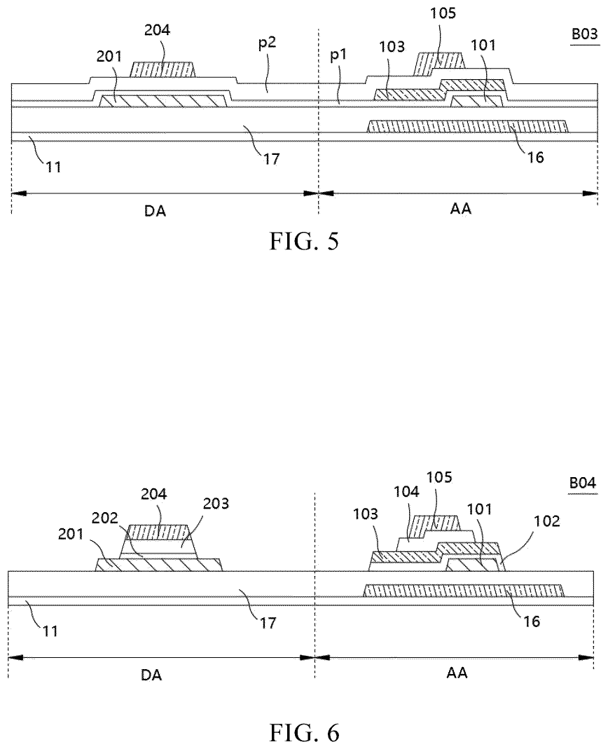

As shown in FIG. 5, in step B03, a second gate 105 and a third gate 204 are formed on the second insulating material layer p2, the second gate 105 overlaps the first channel 1b of the first active layer 103, and the third gate 204 overlaps the second channel 2b of the second active layer 201.

Optionally, the materials of the second gate 105 and the third gate 204 may be formed using a metal element selected from the group consisting of chromium, copper, aluminum, gold, silver, zinc, molybdenum, tantalum, titanium, tungsten, manganese, nickel, iron, neodymium, and cobalt, an alloy containing any of any one of the above metal elements as a component, or an alloy in combination of any of the above metal elements. Further, the second gate 105 and the third gate 204 may have a single-layer structure or a stacked structure of two or more layers.

As shown in FIG. 6, in step B04, the second insulating material layer and the first insulating material layer are sequentially patterned and etched to form a third insulating layer 203, a second insulating layer 104, an etching stop layer 202, and a first insulating layer 102.

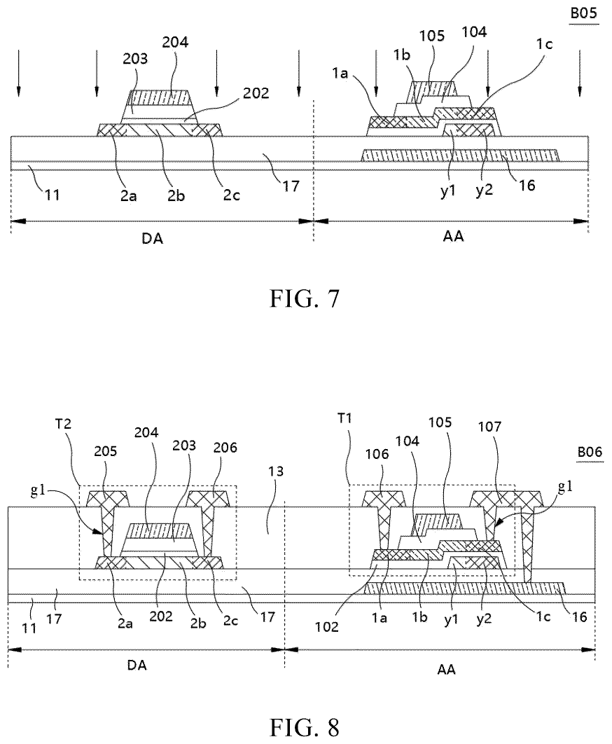

As shown in FIG. 7, in step B05, the first contacting portion 1a and the second contacting portion 1c of the first active layer 103, the third contacting portion 2a and the fourth contacting portion 2c of the second active layer 201, and the conductor portion y2 of the first gate 101 are subjected to overconductivity processing by using the second gate 105 and the third gate 204 as masks.

Optionally, an ion implantation process is used for the conductivity processing. The implanted ions may be N-type or P-type ions, depending on the type of the thin film transistor.

As shown in FIG. 8, in step B06, an interlayer dielectric layer 13 and a source-drain metal layer are sequentially formed on the second gate 105 and the third gate 204. The source-drain metal layer includes a first electrode 106, a second electrode 107, a third electrode 205, and a fourth electrode 206.

Each of the first electrode 106 and the second electrode 107 is connected to the first active layer 103 through a via hole g1, and each of the third electrode 205 and the fourth electrode 206 is connected to the second active layer 201 through a via hole g1.

Optionally, the via hole g1 is formed by dry etching. It should be noted that the etching stop layer 202 may extend toward the direction of the via hole g1 and partially overlap the third electrode 205 and/or the fourth electrode 206.

It can be understood that once the via hole g1 is overetched, the aperture of the via hole g1 will be increased, leading to the reduction of the diffusion distance of the oxygen vacancy toward the direction of the channel. The etching stop layer 202 extends to the vicinity of the via hole g1, and once the via hole g1 is overetched and the aperture is enlarged, the side of the via hole g1 close to the channel is blocked by the etching stop layer 202, and the second active layer 201 covered by the etching stop layer 202 cannot be etched, thereby reducing the risk that oxygen vacancies continue to diffuse toward the channel direction, and accurately controlling the length of the second channel 2b of the second active layer 201.

Optionally, the interlayer dielectric layer 13 may be a single layer or a stacked layer structure, and the material may be oxysilicon. The source-drain metal layer may be formed using a metal element selected from the group consisting of chromium, copper, aluminum, gold, silver, zinc, molybdenum, tantalum, titanium, tungsten, manganese, nickel, iron, neodymium, and cobalt, an alloy containing any of the above metal elements as a component, an alloy containing any of the above metal elements in combination, or the like. Further, the source-drain metal layer may have a single-layer structure or a stacked structure of two or more layers.

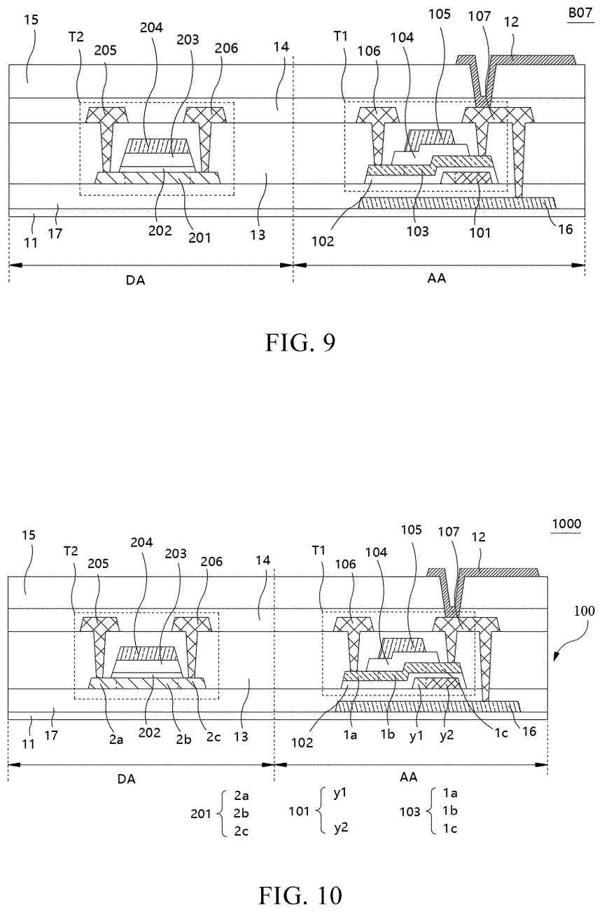

As shown in FIG. 9, in step B07, a passivation layer 14, a planarization layer 15, and an anode 12 are sequentially formed on the source-drain metal layers.

Referring to FIG. 10, correspondingly, an embodiment of the present disclosure further provides a display device 1000 including a display panel 100 as described in any one of the above embodiments.

It should be noted that the structure of the display panel 100 of the display device 1000 provided by the embodiments of the present disclosure is similar to or the same as the structure of the display panel 100 of the above-described embodiments, and details may be described with reference to FIGS. 1 to 9, and thus the description thereof will not be repeated here.

The display device 1000 provided by the embodiment of the present disclosure includes a first thin film transistor T1 located in the display area AA. The first thin film transistor T1 includes a first gate 101 and a second gate 105. The first gate 101 is located on a side of the second gate 105 away from the first electrode 106, and the second gate 105 includes a semiconductor portion y1 and a conductor portion y2 connected to each other, and the conductor portion y2 is located on a side of the semiconductor portion y1 close to the second electrode 107. In a thickness direction of the display panel 100, the second gate 105 overlaps the first channel 1b, and the semiconductor portion y1 partially overlaps the first channel 1b and the second gate 105.

It can be understood that the first gate 101 is provided on the side close to the second electrode 107 to control the output saturation characteristic of the output electrode area of the first thin film transistor T1 so as to improve the output characteristic of the pixel driving transistor. The semiconductor portion y1 is provided to overlap the first channel 1b, and the conductor portion y2 is provided on the side close to the output electrode of the first thin film transistor T1, so that the potential of the semiconductor portion y1 is relative low compared to the potential of the conductor portion y2 based on the larger impedance of the semiconductor portion y1 and the smaller impedance of the conductor portion y2. This configuration reduces the influence of the electric field from the first gate electrode 101 on the first channel 1b, thereby enhancing the service life of the first thin film transistor T1. Additionally, the first gate electrode 101 can generate two different potentials to collaboratively regulate the electric field distribution in the output region of the first thin film transistor T1, achieving control over its output saturation characteristics and improving its stability.

Optionally, the display device 1000 can be applied to various products and used within such products, including, for example, televisions, notebook computers, monitors, billboards, Internet of Things (IoT) devices, and portable electronic devices such as mobile phones, smartphones, tablet personal computers, mobile communication terminals, electronic notepads, e-books, portable multimedia players (PMP), navigation devices, and ultra-mobile personal computers (UMPC).

Furthermore, in some embodiments, the display device 1000 may be applied to wearable devices and used within such wearable devices, including smartwatches, watch phones, glasses-type displays, and head-mounted displays. Additionally, in some embodiments, the display device 1000 may be applied to automotive applications such as instrument panels, central dashboards, or central information displays mounted on dashboards, interior mirror displays that replace side mirrors, and entertainment systems for rear-seat passengers arranged on the back of the front seats.

A display panel and a display device provided by the embodiments of the present disclosure have been described in detail above, and the principles and embodiments of the present disclosure have been described herein by applying specific examples, and the description of the above embodiments is only for helping to understand the technical solutions and core ideas of the present disclosure. Meanwhile, those skilled in the art may change the specific embodiments and the scope of this application according to the ideas of the present disclosure, and in summary, the contents of the present specification should not be construed as limiting the present disclosure.

What is claimed is:

1. A display panel, comprising a display area and a gate driving circuit area located on at least one side of the display area, wherein the display panel comprises:
a substrate; and
a first thin film transistor disposed in the display area, wherein the first thin film transistor comprises a first gate, a first insulating layer, a first active layer, a second insulating layer, a second gate, a first electrode, and a second electrode, the first active layer comprises a first contacting portion, a first channel, and a second contacting portion, the first gate is disposed on the substrate, the first insulating layer covers the first gate, the first active layer is disposed on a side of the first insulating layer away from the substrate, the second insulating layer is disposed on a side of the first active layer away from the substrate, the second gate is disposed on a side of the second insulating layer away from the substrate, the first electrode is connected to the first contacting portion, and the second electrode is connected to the second contacting portion;
wherein the first gate is located on a side of the second gate away from the first electrode, the first gate comprises a semiconductor portion and a conductor portion connected to each other, the conductor portion is located on a side of the semiconductor portion close to the second electrode, the second gate overlaps the first channel in a thickness direction of the display panel, and the semiconductor portion partially overlaps the first channel and the second gate in the thickness direction of the display panel.

2. The display panel of claim 1, wherein a carrier mobility of the semiconductor portion is greater than a carrier mobility of the first channel.

3. The display panel of claim 2, wherein the conductor portion at least partially overlaps the second contacting portion in the thickness direction of the display panel, and the conductor portion partially overlaps the second electrode in the thickness direction of the display panel.

4. The display panel of claim 3, wherein a part of the first insulating layer covers the first gate to form a structure having a height difference, and the first active layer covers the first insulating layer to form the first channel having a height difference.

5. The display panel of claim 1, wherein a material of the first channel is a metal oxide semiconductor, a material of the first insulating layer is a first oxysilicon, and a material of the second insulating layer is a second oxysilicon, and an oxygen content of the second oxysilicon is greater than an oxygen content of the first oxysilicon.

6. The display panel of claim 1, wherein a width of the second insulating layer is greater than a width of the second gate.

7. The display panel of claim 4, wherein the display panel further comprises a second thin film transistor located in the gate driving circuit area, the second thin film transistor comprises a second active layer, an etching stop layer, a third insulating layer, a third gate, a third electrode, and a fourth electrode, the second active layer comprises a third contacting portion, a second channel, and a fourth contacting portion, the second active layer is disposed on the substrate, the etching stop layer, the third insulating layer, and the third gate are sequentially stacked on the second active layer, the third gate overlaps the second channel, the third electrode is connected to the third contacting portion, and the fourth electrode is connected to the fourth contacting portion; and
a carrier mobility of the second channel is greater than the carrier mobility of the first channel, the second active layer is arranged in a same layer as the first gate electrode, and a material of the second channel is the same as a material of the semiconductor portion.

8. The display panel of claim 7, wherein a conductivity of the third contacting portion and a conductivity of the fourth contacting portion are greater than a conductivity of the conductor portion.

9. The display panel of claim 7, wherein a width of the etching stop layer is greater than a width of the third gate.

10. The display panel of claim 7, wherein the etching stop layer and the first insulating layer are made of a same material and are made of a same photomask, the third insulating layer and the second insulating layer are made of a same material and are made of a same photomask, the second active layer and the first gate are made of a same photomask, and the second gate and the third gate are made of a same material and are made of a same photomask.

11. The display panel of claim 1, wherein the display panel is an electroluminescent panel, and the second electrode is connected to an anode.

12. A display device, comprising a display panel, wherein the display panel comprises:
a substrate; and
a first thin film transistor disposed in the display area, wherein the first thin film transistor comprises a first gate, a first insulating layer, a first active layer, a second insulating layer, a second gate, a first electrode, and a second electrode, the first active layer comprises a first contacting portion, a first channel, and a second contacting portion, the first gate is disposed on the substrate, the first insulating layer covers the first gate, the first active layer is disposed on a side of the first insulating layer away from the substrate, the second insulating layer is disposed on a side of the first active layer away from the substrate, the second gate is disposed on a side of the second insulating layer away from the substrate, the first electrode is connected to the first contacting portion, and the second electrode is connected to the second contacting portion;
wherein the first gate is located on a side of the second gate away from the first electrode, the first gate comprises a semiconductor portion and a conductor portion connected to each other, the conductor portion is located on a side of the semiconductor portion close to the second electrode, the second gate overlaps the first channel in a thickness direction of the display panel, and the semiconductor portion partially overlaps the first channel and the second gate in the thickness direction of the display panel.

13. The display device of claim 12, wherein a carrier mobility of the semiconductor portion is greater than a carrier mobility of the first channel.

14. The display device of claim 13, wherein the conductor portion at least partially overlaps the second contacting portion, and the conductor portion partially overlaps the second electrode in a thickness direction of the display panel.

15. The display device of claim 14, wherein a part of the first insulating layer covers the first gate to form a structure having a height difference, and the first active layer covers the first insulating layer to form the first channel having a height difference.

16. The display device of claim 12, wherein a material of the first channel is a metal oxide semiconductor, a material of the first insulating layer is a first oxysilicon, and a material of the second insulating layer is a second oxysilicon, and an oxygen content of the second oxysilicon is greater than an oxygen content of the first oxysilicon.

17. The display device of claim 12, a width of the second insulating layer is greater than a width of the second gate.

18. The display device of claim 15, wherein the display panel further comprises a second thin film transistor located in the gate driving circuit area, the second thin film transistor comprises a second active layer, an etching stop layer, a third insulating layer, a third gate, a third electrode, and a fourth electrode, the second active layer comprises a third contacting portion, a second channel, and a fourth contacting portion, the second active layer is disposed on the substrate, the etching stop layer, the third insulating layer, and the third gate are sequentially stacked on the second active layer, the third gate overlaps the second channel, the third electrode is connected to the third contacting portion, and the fourth electrode is connected to the fourth contacting portion; and
a carrier mobility of the second channel is greater than the carrier mobility of the first channel, the second active layer is arranged in a same layer as the first gate electrode, and a material of the second channel is the same as a material of the semiconductor portion.

19. The display device of claim 18, wherein a conductivity of the third contacting portion and a conductivity of the fourth contacting portion are greater than a conductivity of the conductor portion.

20. The display device of claim 18, wherein a width of the etching stop layer is greater than a width of the third gate.
